(19) United States
(12) Patent Application Publication
(10) Pub. No.: US 2021/0167724 A1
(43) Pub. Date: Jun. 3, 2021

(54) SYSTEM AND METHOD FOR SOLAR PANEL HEAT ENERGY RECOVERY, HEAT ENERGY STORAGE AND GENERATION FROM THE STORED HEAT ENERGY

(71) Applicant: Icarus RT, Inc., Carlsbad, CA (US)

(72) Inventors: Mark Gerard Anderson, Carlsbad, CA (US); Ronald Pitt, Carlsbad, CA (US)

(21) Appl. No.: 17/174,212

(22) Filed: Feb. 11, 2021

Related U.S. Application Data
(63) Continuation of application No. PCT/US2019/044932, filed on Aug. 2, 2019.
(60) Provisional application No. 62/718,321, filed on Aug. 13, 2018.

(51) Int. Cl. H02S 40/42; H02S 50/00; H05K 7/20

(52) U.S. Cl. CPC H02S 40/425; H05K 7/20945; H05K 7/20936; H02S 50/00

(57) ABSTRACT

Systems and methods for cooling solar panels and recovering energy therefrom are disclosed. In one aspect, the system includes at least one solar panel configured to convert at least a portion of incident light into electrical energy. The system also includes a first loop including a heat exchanger configured to receive a first working fluid and circulate the working fluid in proximity to the solar panel so as to extract heat from the solar panel into the working fluid. The system further includes a second loop including an electricity generator configured to receive a second working fluid and generate electricity based on enthalpy of the second working fluid. The first loop and the second loop are configured to transfer heat from the first working fluid to the second working fluid.

### BACKGROUND

### Field

The described technology generally relates to systems and methods for solar panel heat energy recovery and heat energy storage, and in particular, generating electrical energy from heat energy produced by the solar panel.

### Description of the Related Technology

A solar panel is a device generally comprising semiconductor materials configured to convert at least a portion of incident light into electrical energy. Photovoltaic cells included in solar panels, along with the other materials forming the solar panel, absorb a portion of the incident solar energy onto the panel, which can result in heating up the solar panel above an optimum operating temperature. This heating of solar panels can lead to reduced efficiency of solar panels (e.g., in converting the received energy into electricity) that in turn decreases the electrical energy output from the solar panels. To cool down heated solar panels closer to the optimum operating temperature, coolant such as water, may be sprayed on the panels.

### SUMMARY OF CERTAIN INVENTIVE ASPECTS

The systems, methods and devices of this disclosure each have several innovative aspects, no single one of which is solely responsible for the desirable attributes disclosed herein.

Systems which cool solar panels via spraying a coolant or passing air or water directly onto the solar panels do not harvest energy from the coolant. Rather, the coolant (e.g., water) is cooled before being used again to cool the solar panels. Thus, the energy transferred into the coolant ends up being waste energy not used to generate electricity. Embodiments of the described technology solve this problem for solar cells installed on flat panels, or other configurations such as parabolic trough or dish. Other embodiments of the described technology aim to generate electrical energy using heat energy captured from a solar panel, which may be stored for electrical energy generation at a later time.

In one aspect, there is provided a solar panel temperature control system, comprising: at least one solar panel configured to convert at least a portion of incident light into electrical energy; a first loop comprising a heat exchanger configured to receive a first working fluid and circulate the working fluid in proximity to the solar panel so as to extract heat from the solar panel into the working fluid; and a second loop comprising an electricity generator configured to receive a second working fluid and generate electricity based on enthalpy of the second working fluid, wherein the first loop and the second loop are configured to transfer heat from the first working fluid to the second working fluid.

In any of the above or below systems, the system may further comprise: the first working fluid and the second working fluid, wherein the first working fluid comprises a different composition relative to the second working fluid.

In any of the above or below systems, the first working fluid may have a boiling point that is greater than a boiling point of the second working fluid.

In any of the above or below systems, the first working fluid may comprise a water based fluid and the second working fluid may comprise an organic refrigerant.

In any of the above or below systems, the first loop may be fluidly isolated from the second loop, and the first loop may be thermally connected to the second loop.

In any of the above or below systems, the system may further comprise: a storage tank configured to extract heat from the first working fluid and provide heat to the second working fluid.

In any of the above or below systems, the storage tank may be further configured to store heat extracted from the first working fluid at a first time and the system may be configured to provide the stored heat to the second working fluid at a second time after the first time.

In any of the above or below systems, the system may further comprise: a controller configured to control at least one of: cooling of the solar panel, storage of the heat extracted from the first working fluid, and generation of electricity by the electricity generator, based on one or more parameters.

In any of the above or below systems, the controller may be further configured to control each of: the cooling of the solar panel, the storage of the heat extracted from the first working fluid, and the generation of electricity by the electricity generator, based on one or more parameters.

In any of the above or below systems, the second loop may be configured to cycle the second working fluid via an Organic Rankine Cycle (ORC).

In any of the above or below systems, the system may further comprise electricity conditioning circuitry configured to condition the electricity generated by the electricity generator to simulate an IV curve of the solar panel.

In yet another aspect, there is provided a method of controlling a solar panel temperature control system, comprising: converting at least a portion of light incident on at least one solar panel into electrical energy; circulating a first working fluid in proximity to the solar panel via a heat exchanger so as to extract heat from the solar panel into the working fluid; transferring heat from the first working fluid into a second working fluid; and generating electricity via an electricity generator based on enthalpy of the second working fluid.

In any of the above or below methods, the first working fluid may be a different composition relative to the second working fluid.

In any of the above or below methods, the first working fluid may have a boiling point that is greater than a boiling point of the second working fluid.

In any of the above or below methods, the first working fluid may comprise a water based fluid and the second working fluid may comprise an organic refrigerant.

In any of the above or below methods, the first loop may be fluidly isolated from the second loop, and the first loop may be thermally connected to the second loop.

In any of the above or below methods, the method may further comprise: extracting heat from the first working fluid into a storage tank at a first time; and providing heat from the storage tank to the second working fluid at a second time after the first time.

In any of the above or below methods, the method may further comprise: storing heat extracted from the first working fluid in the storage tank; and providing the stored heat from the storage tank to the second working fluid at a later time

In any of the above or below methods, the method may further comprise: controlling, via a controller and based on one or more parameters, at least one of: cooling the solar panel, storing the heat extracted from the first working fluid, and generating electricity by the electricity generator.

In any of the above or below methods, controlling may comprise: controlling, via the controller and based on the one or more parameters, each of: the cooling the solar panel, the storing the heat extracted from the first working fluid, and the generating electricity by the electricity generator.

In any of the above or below methods, the method may further comprise: cycling the second working fluid in a loop via an Organic Rankine Cycle (ORC).

In any of the above or below methods, the method may further comprise: conditioning via electricity conditioning circuitry, the electricity generated by the electricity generator to simulate an IV curve of the solar panel.

### BRIEF DESCRIPTION OF THE DRAWINGS

The disclosed aspects will hereinafter be described in conjunction with the appended drawings, provided to illustrate and not to limit the disclosed aspects, wherein like designations denote like elements.

FIG. 1 is a pressure-volume diagram which illustrates a power cycle in accordance with aspects of this disclosure.

FIG. 2 is a diagram illustrating a solar panel temperature control system in accordance with aspects of this disclosure.

FIG. 3 is a diagram illustrating another example solar panel temperature control system for cooling at least one solar panel in accordance with aspects of this disclosure.

FIG. 4 illustrates one example of a heat exchanger in accordance with aspects of this disclosure.

FIG. 5 illustrates one example of a solar panel temperature control system that includes an array of heat exchangers.

FIG. 6 is a diagram illustrating yet another example of a solar panel temperature control system in accordance with aspects of this disclosure.

FIGS. 7A and 7B illustrate two view of an example condenser and storage tank which can be used in the system of FIG. 6.

### DETAILED DESCRIPTION

Solar panels may have an optimum operating temperature at which electric generation is most efficient. Solar panels may include photovoltaic (PV) modules, which are typically tested at a temperature of 25° C. (about 77° F.), referred to as “the standard test condition” (STC). An “optimum operating temperature” as used herein can be defined as a temperature, such as the standard test condition, above which the performance efficiency of the solar panels begins to see decreases in performance related to increasing temperatures. Depending on the ambient temperature of the environment where they are installed, the resulting temperature in solar panel(s) above the optimum operating temperature can reduce efficiency by about 10-25%. Panel manufacturers may specify a “temperature coefficient (Pmax)” as the maximum power temperature coefficient which determines how much power the panel will lose per degree Celsius the temperature rises above the optimum operating temperature 25° C. For example, the temperature coefficient of certain monocrystalline and polycrystalline PV solar panels might be −0.45% per 1 degree Celsius meaning that for every degree above 25° C., the maximum power of the solar panel falls by 0.45%.

Accordingly, the standard operating temperature of a given solar panel may be defined as the upper limit within a range of operating temperatures in which a solar panel can operate, even though the output of the solar panel within this range may include increasing operating inefficiencies as the temperature increases within this range. Contrast this definition with the aforementioned “optimum operating temperature,” at or below which the solar panel operates best, and above which the efficiency of the solar panel suffers. Thus, under certain circumstances, solar panels may be heated above the optimum operating temperature, negatively affecting output efficiency, even though electricity can still be generated. For example, environmental temperatures, natural cooling (e.g., wind, rain, etc.), heat generated by the photovoltaic (PV) cells in the solar panels, etc. may all affect the operating temperature of the solar panels, contributing to a decrease in efficiency.

Solar panels can perform well in cold weather, even below freezing. However, as mentioned above, heating a solar panel above the optimum operating temperature can result in a reduction in efficiency, and therefore power output. For example, on a hot day the standard operating temperature of a solar panel temperature may exceed 75° C. (167° F.), far above the optimum operating temperature of 25° C. in the STC design implementation. Cooling of solar panels can increase the operating efficiency of the solar panels by bringing heated or high temperature solar panels closer to or below the standard operating temperature, or even better, closer to or below the optimum operating temperature. Certain techniques for cooling panels may include spraying water, which may be actively or passively cooled, onto the panels. However, if the cooling water is to be recycled, it has to be collected off of the solar panels, and because it has at that point been heated, it must be cooled before being reapplied. One aspect of this disclosure relates to recovering a portion of the energy used to heat the coolant, and using the recovered energy to generate electricity.

Other techniques for cooling solar panels may have drawbacks which decrease the overall efficiency of the power generating system. For example, a refrigeration system can in theory be used to cool the solar panels. However, refrigeration systems are inefficient because they require a compressor to increase the pressure of the refrigerant when run through a refrigeration cycle. Running such a compressor will generally draw more electrical energy than is saved by increasing the efficiency of the solar panel, leading to a net decrease in power generation. Thus, cooling solar panels using a refrigeration cycle is generally not sufficiently energy efficient for solar panel installations designed for power generation.

Aspects of this disclosure relate to systems and techniques which may be used to increase the net electric energy production of solar panel systems (which may be referred to as the “efficiency” of the system herein). Such an increase can be achieved through different implementations, alone, or in combination with each other. For example, some aspects relate to use of a pump and heat exchanger in an Organic Rankine Cycle (ORC) for cooling one or more solar panel(s). Further aspects relate to using an organic refrigerant with a heat exchanger to affect the temperature of a corresponding solar panel. Other aspects relate to extracting energy from one or more solar panel(s) (e.g. in the form of heat, also referred to as “waste heat”), using a heat exchanger, and generating additional electricity from the extracted energy.

The following is provided to help further understand the general theories behind thermodynamic cycles, including Rankine cycles and ORCs, to provide further context for aspects of the implementations described herein:

### Thermodynamic Cycles

Thermodynamic cycles include a series of processes (changes in state that result in a return to the initial state) involving work and transfer of heat into and out of a system. During the process, pressure, temperature, and other state variables of a working fluid may change due to the heat and/or work supplied to and extracted from the working fluid as the working fluid moves through the cycle. In passing through a thermodynamic power or heat pump cycle, the working fluid receives heat from a warm source and converts the received heat into useful work. The remaining heat (from which useful work is not or cannot be further extracted) is transferred to a cold sink, thereby acting as a heat engine (converting thermal energy to mechanical energy). In the opposite case, the cycle is reversed and work is used to move heat from a cold source to be transferred to a warm sink, acting as a heat pump.

Throughout the process in a closed loop, the system is in thermodynamic equilibrium at each point in the cycle. In the ideal case, this enables the cycle to be reversible (meaning that the change in entropy of the closed system, which is a function of the system state, is zero). In a closed loop, the net change in all system conditions is zero, because the fluid returns to its original temperature and pressure. The first law of thermodynamics applies, meaning that energy cannot be created nor destroyed. There is no net change of energy over the complete cycle. Also per the first law of thermodynamics, the net heat gain is ideally equal to the net work output over the complete cycle. Constant uninterrupted operation of the process sanctions continuous operation.

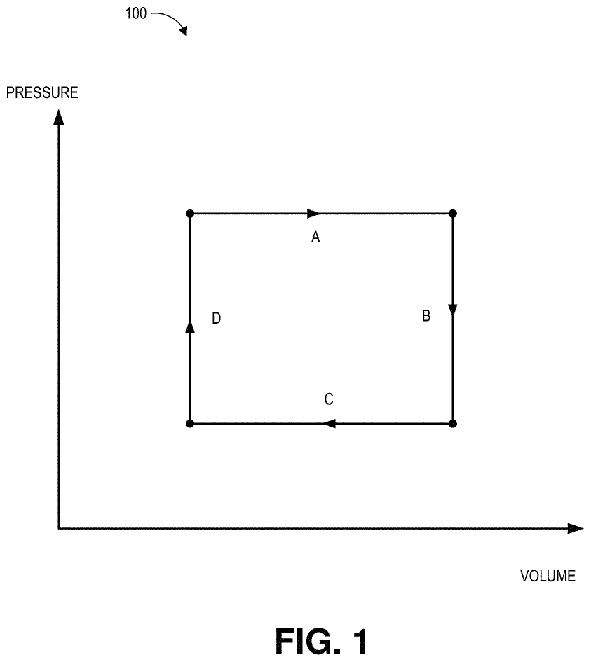

There are two primary classes of thermodynamic cycles. Power cycles convert heat gain into mechanical work. Heat pump cycles transfer heat from cool sources to warmer temperatures by applying mechanical work. FIG. 1 is a pressure-volume diagram which illustrates a power cycle to provide context for aspects of this disclosure. As shown in FIG. 1, the pressure—volume diagram 100 indicates a clockwise flow direction for power cycles, whereas a heat pump pressure-volume diagram would include a counter clockwise cycle. Similarly on temperature—entropy diagrams, the clockwise and counter clockwise flow directions respective indicate power and heat pump cycles. The illustrated flow include four processes A, B, C, and D ideally involving a change in only one parameter (pressure or volume) at each stage.

### Rankine Cycle

A Rankine cycle is one of many common thermodynamic cycles. The Rankine cycle is a thermodynamic power cycle primarily used to convert heat gain into work output. The heat is generally supplied to a closed loop system. The Rankine cycle often refers to a steam cycle as typically used in power plants. Utility scale thermal power plants typically use water and steam as the working fluid in a Rankine cycle and provide an estimated 85% of electricity produced globally today. In a Rankine cycle, three things generally happen to generate work output:

1. Heat is added at a temperature greater than that of the working fluid to alter the fluid's characteristics (e.g., boiling the working fluid);

2. A certain amount of energy from heat gained in step 1 is used to perform work (e.g., generate power); and

3. The balance of the heat not used to performed work is removed at a temperature that is lower than the temperature of the working fluid to condense the working fluid.

The amount of power that can be produced by a Rankine cycle is a function of the temperature difference between the heat source and the cold sink. More mechanical power can be efficiently extracted out of heat energy with a higher temperature difference. Low inlet temperature of steam turbines (as contrasted with high combustion temperatures in gas turbines) is one of the reasons why the Rankine cycle is practical to recover rejected waste heat in gas turbine plants. Cold sinks used in these power plants can be rivers, cooling towers or the sea. The Rankine cycle power plant efficiency is limited by the lower practical temperature of the working fluid on the cold side.

The working fluid used in the Rankine cycle is generally processed in a continuous closed loop. In certain implementations, such as in a power plant, water vapor is produced by the plant cooling systems when cooling the working fluid. Exhaust heat is produced from the cooling system in cooling the working fluid.

Typically, for non-solar utility scale power plants, water is used for the working fluid, because the operating temperatures and differentials in these power plant cycles are high enough to provide the phase changes between liquid water and steam. However, because water requires such a high temperature or temperature swing, it may not be efficient to use it in certain relatively lower temperature or temperature differential applications which nonetheless produce external heat, for potential power generation. For example, a solar power application does not have a high enough temperature to substantially vaporize liquid water into steam. Similarly, there are numerous applications (e.g., low grade waste heat recovery systems) in which the operating temperature is not sufficient to vaporize water. Therefore, in certain applications, a refrigerant, or high molecular mass fluid typically known as organic fluid, can be used in an ORC system to cool the heat source and generate supplementary electricity.

### Organic Rankine Cycle (ORC)

This disclosure relates to the use of an ORC for the recovery of waste heat at low/medium temperatures (e.g., at temperatures below the boiling point of water), and particularly to the use of an ORC to cool a solar panel system. For example, in the solar panel implementation, the ORC may be used to cool solar panels to within a defined range of temperatures within which the solar panel can be operated more efficiently. Depending on the implementation, the low temperature heat discharged in several industrial applications cannot be recovered with a traditional bottom steam cycle. However, using an ORC as described in this disclosure, this waste heat can be converted into electrical energy. The choice of the fluid used as the working fluid for the ORC may be important for a performance of the cycle because the thermophysical properties of the selected working fluid may be related to the operating temperatures of the particular implementation.

ORC may use an organic fluid as the working fluid in place of water and steam. ORC efficiency may be lower than a non-organic Rankine cycle due to the lower temperature of operation. However, ORC may still be practical for heat energy recovery because of the low cost required to gather heat and the broad opportunities for low-grade waste heat recovery. An organic fluid as described herein may refer to an organic compound of low boiling point, such as a high molecular mass fluid (e.g., higher than the molecular mass of water) with a boiling point (liquid-vapor phase change) at a low temperature compared to that of the liquid water-steam phase change. The organic fluid for the ORC cycle may be selected based upon its particular boiling point relative to the standard operating temperature of the heat source (e.g., solar panel(s)) used to vaporize the working fluid. That is, the boiling point may be selected to be lower than the standard operating temperature of the heat source such that the working fluid can be vaporized effectively by the heat source during standard operating conditions.

The boiling point of the working fluid may depend upon the state of the working fluid. For example, while the boiling point of the working fluid may be defined at atmospheric temperatures, the relevant boiling point of the working fluid is the boiling point at the pressure experienced by the working fluid when exposed to the heat source. For example, since the working fluid should be vaporized by the heat source in an ORC, the boiling point of the working fluid may be less than the standard operating temperature of the heat source, as defined further herein. Other factors that may weigh into the selection of the working fluid include the lower threshold temperatures and pressures of the application. The organic fluid selected may also be selected to be economical, nontoxic, nonflammable, environmentally safe (low Global Warming Potential), and/or stable. The fluid may allow a high utilization of the available energy from the lower temperature heat source. The freezing point of the fluid may be lower than the lowest temperature of the cycle.

The proper selection of a working fluid allows ORC heat recovery from moderate temperature sources such as industrial waste heat or solar panel(s) which may have a standard operating temperature of 70-90° C. However, solar panel(s) designed to operate in specific environments (e.g., cold environments where a standard operating temperature of 70-90° C. may not occur) can be developed to have a standard operating temperature outside of the 70-90° C. range. In general, the standard operating temperature of a solar panel, as used herein, is the upper limit within a range of temperatures within which the solar panel can operate to some extent, even with inefficiencies, which is at and above the optimum operating temperature. Thus, in certain embodiments, the standard operating temperature from which it is desirable to cool the solar panel(s) may depend on the particular design of the solar panel(s) and the corresponding optimum operating temperature thereof. Traditional water-based heat recovery systems cannot effectively generate electricity within these operating temperatures. By using organic fluid as a working fluid, the low-temperature “low-grade waste heat” can be converted into practical work typically used to generate electricity. The characteristics and working principles of the ORC may be similar to those of a traditional, non-organic Rankine cycle, such as described generically above with reference to FIG. 1.

In an ideal ORC, expansion is isentropic and the evaporation and condensation processes are isobaric. However, in real world implementations, irreversibilities such as heat loss lower the overall efficiency of the ORC.

ORC technology has many possible implementations including a solar panel implementation and other solar applications such as parabolic trough concentrated solar thermal, where the ORC technology can be used in lieu of the usual steam Rankine cycle. ORC allows power generation at lower capacities and with a lower collector temperature, and hence the possibility for low-cost, small scale decentralized concentrating solar power (CSP) units.

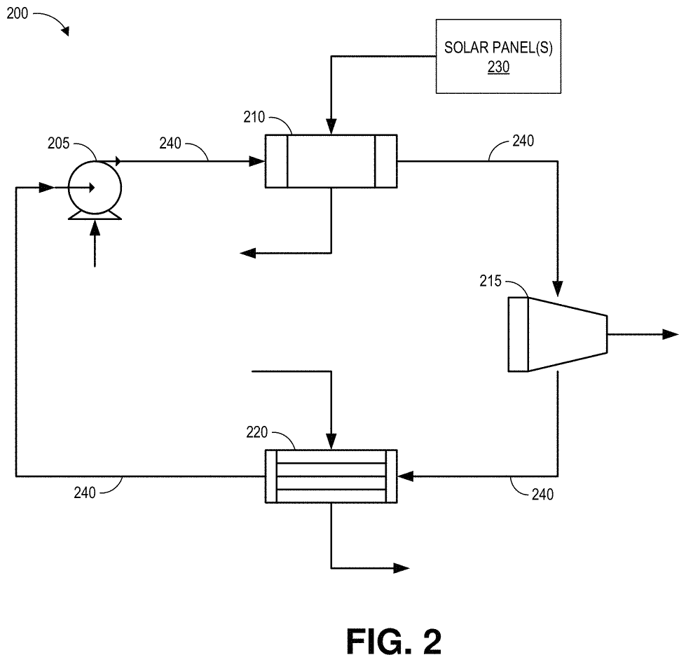

FIG. 2 is a diagram illustrating a solar panel temperature control system 200 in accordance with aspects of this disclosure. As used herein, the term “solar panel temperature control system” can refer to a system that provides the benefits associated with controlling (e.g., cooling) the solar panels and/or the energy recovery and additional electricity generation by using the waste heat from a solar panel system. Thus, in the present example, the solar panel system 200 may be configured to employ an ORC for cooling a heat source, such as one or more solar panel(s) and/or, in some embodiments, generating electricity using “waste heat” extracted from the solar panel into a working fluid.

The system 200 can include a pump 205, a heat exchanger 210 (e.g., an evaporator), a turbine-generator 215, a condenser 220, and a solar panel 230. Although FIG. 2 is discussed in connection with a solar panel 230, this disclosure is not limited thereto, and in other embodiments, the solar panel 230 may be replaced by another heat source for which cooling the heat source is desirable. For example, the heat source may include a gas turbine plant or another industrial process that generates waste heat.

Returning to FIG. 2, the working fluid is pumped via pump 205 as a liquid to the heat exchanger 210 which receives heat from the solar panel 230. The pump 205 may be any suitable device configured to receive, increase the pressure of, and/or otherwise regulate the flow of the working fluid within at least some portion(s) of system 200. The working fluid may comprise an organic refrigerant. The heat exchanger 210 may be configured to receive the working fluid from the pump 205 and circulate the working fluid in proximity to the solar panel 230 so as to extract and transfer heat from the solar panel 230 into the working fluid. The heat exchanger 210 can be any suitable device that transfers heat from the solar panel 230 such that the working fluid at least partially undergoes a phase change from liquid to gas. The efficiency of the system will increase, for example, as the temperature of the working fluid increases, as in when the amount of working fluid converted into a gas is increased. This may be accomplished via the selection of the working fluid with desirable characteristics as described below.

After the working fluid is at least partially evaporated by the heat exchanger 210, it is then passed through the turbine-generator 215 (also referred to simply as a turbine) where the working fluid exhausts pressure as the turbine-generator 215 extracts energy from the working fluid. The turbine-generator 215 may be any suitable electricity generator configured to receive a working fluid (e.g., from the heat exchanger 210) and generate electricity based on the enthalpy of the working fluid. For example, the turbine-generator 215 may be configured to generate electricity using the internal energy, pressure and/or volume of the working fluid. Depending on the embodiment, the turbine-generator 215 may be any suitable electricity generator, embodied as a turbo-expander, turbo-generator, steam turbine, scroll turbine, etc., and any related components to generate electricity.

The working fluid can be provided to the condenser 220, or a heat sink, where the working fluid drops in temperature and re-condenses, for example, before being fed back into the pump 205. The condenser 220 may be any suitable device configured to receive, cool and condense a working fluid such that at least a portion of the working fluid undergoes a partial or complete phase change from gas to liquid. For example, the condenser 220 can be configured to receive the working fluid from the turbine-generator 215, circulate the working fluid in proximity to a cold source so as to extract heat from the working fluid into the cold source, such that at least a portion of the working fluid undergoes a phase change from gas to liquid. The condenser 220 can be configured to supply the working fluid to the pump 205.

In certain implementations, the turbo-generator 215 uses medium-to-high-temperature thermal oil to preheat and vaporize (e.g., further vaporize) the organic working fluid received from the heat exchanger 210. The organic fluid vapor rotates the turbine of the turbine-generator 215, which is directly coupled to additional electricity-generating components, resulting in, for example, clean, reliable electric power. The exhaust vapor from the turbine-generator 215 may flow through a regenerator (not illustrated), where the regenerator heats or cools the working fluid which is then provided to the condenser 220 and condensed and cooled. The working fluid is then pumped again, via the pump 205 into the heat exchanger 210, thus completing the closed-cycle operation.

The system shown in FIG. 2 may be adapted to cool the solar panel by circulating the working fluid using different types of cycles. However, as described above, a refrigeration cycle often requires a compressor that requires more power than a pump, and thus may consume more electricity than can be gained in extracting energy recovered by the heat transferred into the working fluid. Accordingly, some aspects of this disclosure relate to the implementation of systems that can be implemented within non-refrigeration cycles that don't require a high energy compressor. In order to operate within a non-refrigeration cycle, in certain embodiments, the pump 205 may be configured to regulate the flow of the working fluid at an operating pressure at which the working fluid is supplied to the heat exchanger, for example, the operating pressure being lower than the pressure used in a refrigeration cycle. For example, the system of FIG. 2 can facilitate the use of organic fluids (such as an organic refrigerant), which may be used in an ORC. An ORC can be run using a pump (e.g., the pump 205 of FIG. 2) that consumes considerably less energy than a compressor. Accordingly, certain solar panel cooling systems may not include a compressor, thereby decreasing the energy consumption of the cooling system.

In certain implementations, the energy used by the pump 205 may be less than the additional energy generated by the increase in efficiency of a solar panel cooled with the organic fluid. For example, a system similar to that shown in FIG. 2 may be implemented with a pump and heat exchanger(s), to cool and improve efficiency of the solar panel(s), resulting in increased power generation, with or without the electricity generator. In other embodiments, the pump 205 may consume less energy than is generated by the electricity generator 215. Thus, the system 200 can provide increased overall power generation for example, with an ORC cycle using the organic fluid, than a similar system using only solar panel(s) without additional cooling and/or power-generating components, or a solar power system that uses a refrigeration cycle.

### Working Fluid Characteristics

There are options available for the selection of a working fluid for use in the low-grade waste heat recovery and/or ORC electricity generation systems described herein. Suitable working fluids are currently being developed and brought to market in larger numbers. Refrigerants, which are organic fluids, historically had characteristics making them undesirable for environmental reasons. Recently developed fluids are designed with these challenges in mind, and are therefore much more appealing from an environmental standpoint. Some of the new fluids have better characteristics for low-grade waste heat recovery. Selection of the proper working fluid can be particularly important in lower temperature cycles because heat transfer inefficiencies are closely related to the temperature differences, operating conditions, and thermodynamic characteristics of the fluid.

For solar panel embodiments, the locations at which solar panels are likely to be deployed have vastly different temperature profiles, and may require the selection of different fluid, and/or blends of fluids. Certain fluid characteristics which may be important in selecting and evaluating a working fluid for use in the described technology include:

a) Isentropic saturation vapor curve. Since one aspect of the described ORC technique focuses on the recovery of low-grade heat power, a superheated approach like the traditional Rankine cycle may not be appropriate. Therefore, a lower amount of superheating at the exhaust of the heat exchanger 220 is desirable. Thus, “wet” fluids (e.g., fluids that are in a two-phase state at the end of the expansion) are not ideal.

b) Low freezing point, high stability temperature. Unlike water, organic fluids usually suffer chemical deteriorations and decomposition at higher temperatures. The maximum heat source temperature is thus limited by the chemical stability of the working fluid. The freezing point should be lower than the lowest temperature in the cycle.

c) High heat of vaporization and density. A fluid with a high latent heat and density will absorb more energy from the source in the heat exchanger 210 and thus reduce the required flow rate, the size of the facility, and the pump consumption. This leads to lower energy consumption in running the pump 205 and also can reduce the wear of the components in the system 300, leading to a longer life cycle.

d) Other important characteristics for the working fluid which may be considered include: low environmental impact (e.g., ozone depletion potential and global warming potential), safety (e.g., non-corrosive, non-flammable, and non-toxic), good availability and low cost, and acceptable pressures and operating range.

According to certain embodiments, the molecular mass of the working fluid is greater than that of water. The molecular mass of the working fluid may also be selected to reduce the rotation speed of the turbine, lower the pressures within the closed system, and reduce or eliminate erosion of the metal parts and/or blades within the closed system.

In certain embodiments, the working fluid may be selected to have a boiling point in the range of about −18° C. (0° F.) to about 66° C. (150° F.) at the operational pressure of the working fluid when within the heat exchanger. However, the boiling point of the working fluid may be below about −18° C. (0° F.) or above about 66° C. (150° F.), depending on the implementation. In certain implementations, the operational pressure of the working fluid within the heat exchanger may range between 50 psi and 150 psi, or higher. In certain implementations, the boiling point of the working fluid, under pressure (i.e. within the operating pressure of the working fluid within the heat exchanger), may be less than the standard operating temperature of the solar panel. Thus, the boiling point of the working fluid may be selected based on such that the boiling point of the working fluid when under the expected range of pressures when passing through the heat exchanger, allows for the working fluid to at least partially undergo a phase change from liquid to gas, when encountering solar panel temperatures at or above the standard operating temperature.

Depending on the implementation, the standard operating temperature for a given solar panel may be within the range of about −18° C. (0° F.) to about 93° C. (200° F.). However, in many embodiments, the standard operating temperature of a solar panel may be in the range of about 21-77° C. (70-170° F.). The standard operating temperature of 21-77° C. (70-170° F.) may comprise the range of temperatures at which the solar panels can operate, but within which the efficiency of the solar panel's electricity generation is increased compared to standalone solar panel(s) which are not cooled. Thus, the working fluid may be selected to have a boiling point that is less than the standard operating temperature of the solar panel. In one embodiment, the working fluid may have a boiling point of about −4° F. at atmospheric conditions.

Evaluating ORC cycles requires analyzing the equations of mass and energy balance, heat transfer, pressure drop, efficiency, and other variables. ORC simulation models will be either steady-state or dynamic. Another important piece of ORC modeling is the addition of the organic fluid thermodynamic properties to a database. The properties for new or particularly unreleased fluids are not commonly available and must be generated to be included, as needed. Multi-parameter equations of state are be preferred, using properties databases, available for simulation models.

### Refrigerants

Refrigerants are organic fluids which may be composed of organic substance(s) or a blend of substances, usually fluid, which may be designed for use in a heat pump and/or refrigeration cycles. In many applications, the refrigerant transitions from a liquid to gas and back to liquid as it moves completely through the process cycle. As discussed above, an ideal refrigerant would have favorable thermodynamic properties, be non-corrosive, safe, non-toxic and nonflammable. The ideal refrigerant would also not cause ozone depletion or climate change.

Certain thermodynamic properties which may be important for fluid selection for low-grade waste heat recovery include a low boiling point below the target temperature (e.g., the operating temperature at which the heat source is desired to be cooled), high heat of vaporization, moderate density as a liquid compared to relatively high density in gaseous form, and a high critical temperature. Boiling point and gas density are both functions of pressure. Thus, proper selection of refrigerants can result in better performance by considering the operating pressures for each particular application.

The organic refrigerants which may be suitable for the described ORC solar panel cooling system may include fluorine-based organic refrigerants, and preferably, without chlorine, to avoid chlorine radicals and their corresponding environmental pitfalls. For example, saturated organic refrigerants, such as Hydro-Fluoro Carbon based compositions may be implemented. Unsaturated organic refrigerants such as Hydro-Fluoro-Olefin-based compositions may be implemented. One such example is DR-14 (from The Chemours Company), which is a Hydro-Fluoro-Olefin-based fluid with no ozone depletion potentials and low global warming potentials. DR-14 remains chemically stable at least up to the maximum temperature tested of 250° C., and thus can be implemented within low grade temperature heat recovery systems. The thermodynamic cycle performance of DR-14 over a range of conditions representative of potential applications was evaluated by the manufacturer through computational modeling and compared to HFC-134a and HFC-245fa. DR-14, along with DR-12 and DR-2 could enable more environmentally sustainable heat pump platforms for the utilization of abundantly available low temperature heat to meet heating duties at higher temperatures and with higher energy efficiencies than incumbent working fluids.

### Example Embodiment of ORC Solar Panel Installation

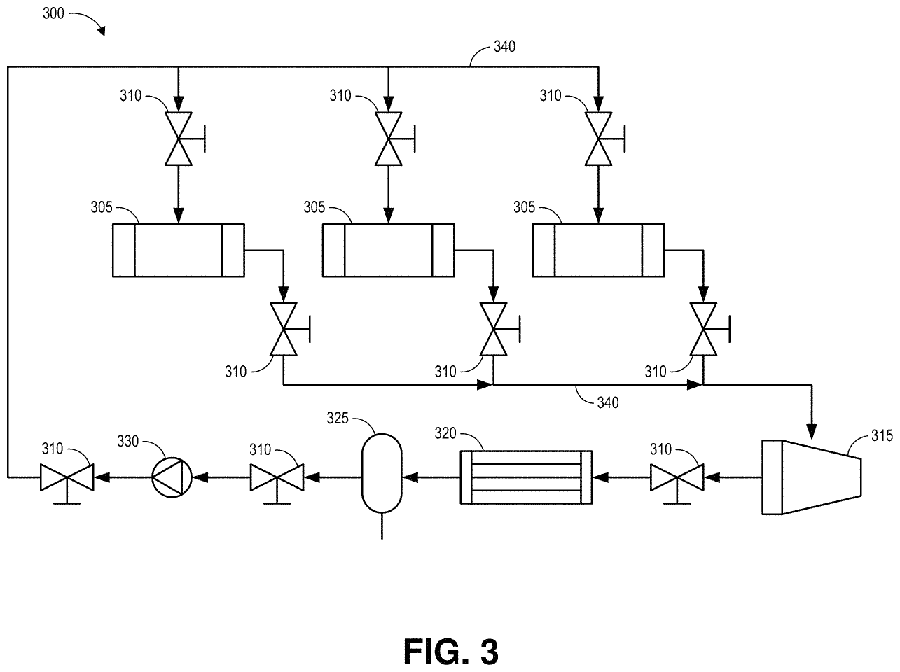

FIG. 3 is a diagram illustrating an example solar panel temperature control system 300 for cooling at least one solar panel in accordance with aspects of this disclosure. System 300 can enhance performance of one or more solar panel(s) by cooling the heated panel(s), to increase panel efficiency, and/or converting energy removed from the heated panel into electrical energy. The solar panel temperature control system 300 includes a plurality of heat exchangers 305, configured in parallel and/or in series, a plurality of isolation valves 310, a turbine 315, a condenser 320, an accumulator 325, and a pump 330. The common components in FIG. 3 can function substantially similar to those described in similar terms with respect to FIG. 2. Although not illustrated, one or more of each of a fluid temperature sensor, a pressure sensor, a flow sensor, a solar panel temperature sensor, and a voltage sensor may be installed into the system 300 to provide feedback to a control system for controlling the system 300 (e.g., controlling the flow of the working fluid via pump 330).

Each of the heat exchangers 305 may be configured to circulate a working fluid in proximity to a corresponding solar panel. Each corresponding solar panel is not illustrated, but can be easily understood with reference to the heat exchanger 210 and corresponding solar panel 230 in FIG. 2. For example, each of the heat exchangers 305 may be configured to receive the working fluid from the pump 330 and circulate the working fluid in proximity to the solar panel so as to extract heat from the solar panel into the working fluid such that the working fluid undergoes a phase change from liquid to gas. Depending on the embodiment, there may be more or fewer isolation valves 310 than illustrated in FIG. 3. It will be understood that the general aspects of the systems described herein can be provided with different quantities of components. For example, one or more pumps may flow fluid through one or more heat exchangers, which may each correspond with one or more solar panels, and vice versa. Thus, a single solar panel need not correspond with a single heat exchanger, etc.

In certain implementations, the turbine 315 may comprise a micro turbine/generator combo. The turbine 315 may be configured to receive the working fluid from the heat exchanger 305 and generate electricity based on the enthalpy of the working fluid. The condenser 320 may be configured to receive the working fluid from the turbine 315, circulate the working fluid in proximity to a cold source (not illustrated) so as to extract heat from the working fluid into the cold source such that the working fluid undergoes a phase change from gas to liquid, and supply the working fluid to the pump 330 via the accumulator 325. The accumulator 325 may be configured to remove excess gas from the working fluid before the working fluid is supplied to the pump 330, such that gas is prevented from reaching the pump 330.

The pump 330 may be configured to pump and regulate flow of a cooled working fluid to the heat exchanger 305 and solar panel via a heat collector piping. The heated working fluid leaving the heat exchanger 305 is then transported to the turbine 315, which may comprise a turboexpander like a micro-turbine, scroll turbine, Tesla Disc turbine, Stirling engine or similar device where energy of the fluid is first converted into mechanical energy and then into electrical energy. The working fluid leaving the turbine 315 may be cooled by the condenser 320 (such as a water radiator) before returning the cooled working fluid to the pump 330 for circulating to the heat exchanger 305 again.

The pump 330 may be configured to regulate the flow and/or increase the pressure of the working fluid to an operating pressure at which the working fluid is supplied to the heat exchanger. For example, the operating pressure may be lower than the pressure used in a refrigeration cycle. By employing an operating pressure that is lower than the pressure for a typical refrigeration cycle, the pump 330 may consume less energy that is required by a compressor to achieve pressures required for a refrigeration cycle. Thus, less energy is lost in pressurizing the working fluid. In one embodiment, the pump 330 consumes less energy than is produced by the turbine 315, thereby enabling the system to have net positive energy production.

In some implementations, the pump 330 may include a variable speed pump configured to adjust the pressure of the working fluid supplied to the heat exchanger based on the temperature of the working fluid. The variable speed pump may be configured to adjust the amount of heat exchanged between the solar panel and the working fluid by controlling the flow of the working fluid. For example, an increase in the flow of the working fluid may result in greater heat exchange. The variable speed pump may also maintain the flow below a certain threshold level to ensure a sufficient amount of vaporization of the working fluid.

By way of example, one embodiment of the described technology cools a solar panel by pumping a cool working fluid through the panel then collecting a hot working fluid for converting energy of the hot fluid into mechanical energy then into electrical energy. Thus, the performance (e.g., the efficiency of converting incident light into electrical energy) of the solar panel(s) can be increased by maintaining the actual panel temperature closer to the solar panel's optimum operating temperature and/or by harvesting electrical energy from the working fluid used to cool the panel. That is, the described solar panel temperature control system may increase the overall system efficiency by at least two mechanisms: i) increasing the efficiency of the solar panel(s) by cooling the solar panel(s) to a more efficient operating temperature (e.g., below the standard operating temperature, and closer to or below the optimum operating temperature as defined herein) and/or ii) generating additional electricity from the heated working fluid using an electricity generator. Depending on the embodiment, either or both of these mechanisms may increase the efficiency of the overall solar panel temperature control system. This efficiency is increased, relative to the standalone performance efficiency of the same standalone system with the same solar panel(s), but without the cooling features, and/or without additional harvested electrical energy from the heated working fluid.

Depending on the embodiment, efficiencies of the solar panel temperature control system can be improved. For example, the efficiency of the solar panel(s), solely by cooling, can be increased by about 1%, 2%, 3%, 4%, 5%, 6%, 7%, 8%, 9%, or 10%, or any range therebetween. In some embodiments, the solar panel efficiency can be increased by about 5-10%. In some embodiments, the solar panel efficiency can be increased by at least 5%. Theoretical increases in efficiency are available up to about 20%, which falls just below the 25% solar panel efficiency loss due to high temperature conditions.

System efficiency improvements solely based upon the additional harvested energy can be about 1%, 2%, 3%, 4%, 5%, 6%, 7%, 8%, 9%, 10%, 11%, 12%, 13%, 14%, 15%, or any range therebetween. In some embodiments, the system efficiency can be increased by about 5-15%, or more narrowly, 10-15%. In some embodiments, the system efficiency can be increased by at least 5%, and in some embodiments, at least 10%, and in some embodiments, about 5-15%, and in some embodiments, about 10-15%. Theoretical increases in efficiency are possible up to about 25% or more.

Thus, the overall increase in efficiency realized by embodiments that include both the solar panel cooling and heat recovery aspects of the solar panel temperature control system may be at least about 1%. In certain embodiments, the overall increase in efficiency may be greater than 1%, for example, about 2%, 3%, 4%, 5%, 9%, 15%, 20%, 25%, or greater. In some embodiments, the overall system efficiency can be increased by at least 5%, and in some embodiments, at least 10%, at least 15%, at least 20%, or at least 25%, and in some embodiments, about 5-25%, about 10-20%, about 10-15%, or about 15-20%. In certain applications, it may be desirable to achieve an increase in the overall efficiency of the solar panel temperature control system of at least 5% such that the costs of installation and maintaining the improved system is economical.

Thus, the overall efficiency of the solar panel temperature control system may be greater than the combined standalone efficiency of a standalone solar panel(s) system due to cooling of the panel(s), and/or the generation of electricity by the electricity generator 315 based on the enthalpy of the heated working fluid. That is, the power generation of the system, for example, due to improved performance of the solar panels when cooled and/or additional power generated by capturing waste-heat, is greater than the amount of power generated by the same solar panel(s) without the inclusion of the cooling system and/or electricity generator.

It will be readily understood that, even though the solar panels in FIG. 3 are not shown, the heat exchanger 305 may be fitted below or in an adjacent area to the solar panels and are connected to the pump 330 for transporting the cool working fluid to the solar panel. The working fluid can be transported through system 300 (FIG. 3) and system 200 (FIG. 2) via any suitable piping for transporting working fluid.

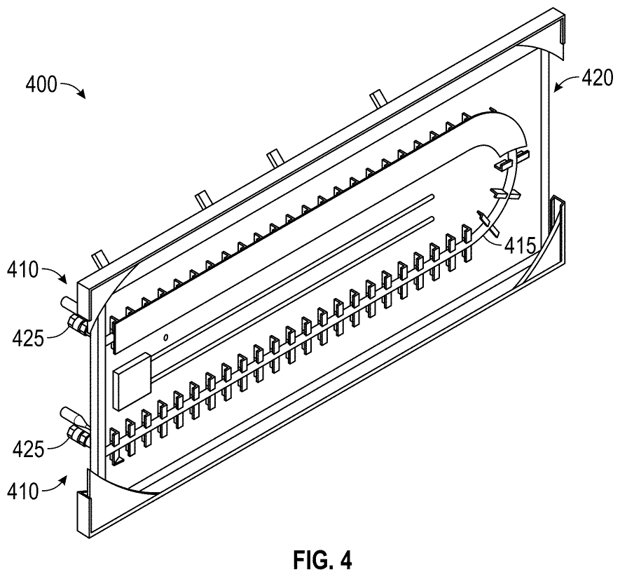

FIG. 4 illustrates one example of a heat exchanger 400 in accordance with aspects of this disclosure. Heat exchanger 400 is an embodiment of heat exchangers 210 and 305 in FIGS. 2 and 3, respectively.

The heat exchanger 400 may include ports 410 to act as a respective inlet and outlet for transporting working fluid through heat collector piping 415 extending through a body 420 of heat exchanger 400. Piping 415 can include one or more bends, or otherwise wrap through the body 420 to provide increased surface area and improved heat transfer from a corresponding proximate solar panel. The heat exchanger 400 can include a hydraulic valve 425 corresponding to each of ports 410, to provide selective fluid communication therethrough. The heat exchanger 400 can include sensors, such as a combined pressure-temperature indicator on either side of valve 425 for first determining pressure and temperature and then regulating the flow and heat exchange of the system to improve efficiency.

The heat collector piping 415 can comprise any suitable configuration for a heat exchanger. For example, a low-pressure copper tubing used for drinking water can be used, for example, with dimensions: ½″ tube size, 5/8″ OD, 0.028″ thickness and 0.569″ ID. The heat collector piping may be modified with a fin configuration for reducing length of the piping. In one example, the pump can produce the fluid with 70 psi pressure having flow rate of about 0.06 gpm. The heat collector piping 415 can be configured for compatibility with various working fluids, such as various organic fluids.

The working fluid can be flowed to and from the ports 410 of heat exchanger 400 with other system piping that is similar to the heat collector piping 415 of heat exchanger 400. For example, with reference again to FIGS. 2 and 3, system piping 240, 340, respectively, can extend between the various components shown. In some embodiments, the components shown may be integrally formed, or immediately adjacent, without needing system piping. The heat collector and/or system piping may be insulated to improve efficiency by retaining energy in the hot working fluid going to the turbo-expander. For the system piping, a medium pressure copper tubing for drinking water can be used with dimensions: ½″ tube size, ⅝″ OD, 0.04″ thickness and 0.545″ ID. Other tubing such as aluminum and PEX tubing, or high-density polyethylene (HDPE) may be used. Compatibility between the material of the tubing and the working fluid may be a factor for consideration when selecting a particular tubing and working fluid combination. For example, when using copper tubing incompatible working fluids may include ammonia, oxygen, fluids with high sulfur content, chlorides, sulfates; aluminum tubing may be incompatible with a chloride working fluid; when using stainless steel tubing, chloride may be incompatible, and an inhibitor with aluminum tubing to maintain a clean heat transfer surface may be advantageous when using water as the working fluid.

As described above, the systems herein can include sensors of various types. For example, a combined pressure-temperature indicator may be installed prior to the electricity generator to measure the pressure and temperature, and a flow controller may regulate the flow according to the pressure. The fluid leaving the electricity generator can be regulated by a flow controller, before entering into the condenser for further cooling by cold water and ice. The flow controllers with low flow panel mount and a protective case may be used.

The cool working fluid leaving the condenser can be measured by a combined pressure-temperature indicator, and the pressure and/or temperature of the working fluid can be adjusted before entering into the pump again.

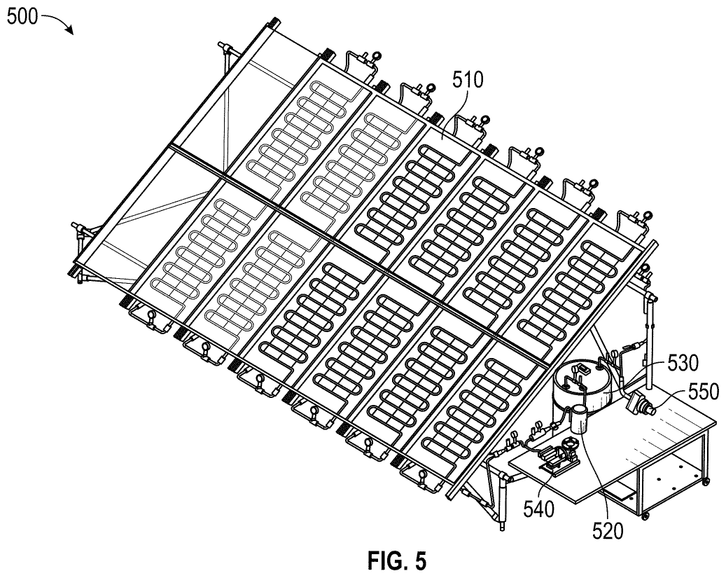

FIG. 5 illustrates one example of a solar panel temperature control system 500 that includes an array of heat exchangers 510. The heat exchangers 510 can be similar to those shown in FIGS. 2-4, and otherwise described herein. The system 500 can include a solar panel corresponding to each heat exchanger 510. The system 500 can include electricity generator 550, condenser 530, accumulator 520, and pump 540, and piping, gauging, and sensors as shown. The system 500 can operate similarly to systems 200 and 300 (FIGS. 2 and 3) in parallel and series configurations.

In some implementations, the system may comprise a parabolic trough or dish. The solar cells may be arranged to line a parabolic trough and may be covered with a reflective film or coating that absorbs the energy from sunlight at a wavelength that the module can convert and reflects or concentrates the rest onto the additional heat collector installed in front of the trough as in a classic concentrated solar thermal collector with a mirror, like a parabolic trough or dish. The working fluid absorbs heat from the back of the trough or dish as in the flat panel case and then is further heated as it flows into the collector installed in front of the trough or dish. This may increase the electrical energy generated at the turbine due to the increased enthalpy of the working fluid.

In one embodiment, a system for enhancing performance of a solar panel or an array of solar panels by cooling the heated solar cells and converting energy from the heated panel into electrical energy; the system comprising: a pump pumped a cool working fluid to the solar panel via a heat collector piping with a pressure-temperature indicator and a valve in the middle; a device, adapted to receive a hot working fluid leaving the solar panel via an insulated piping for extracting energy and converting into mechanical energy before converting into electrical energy, wherein the insulated water radiator piping collected the hot working fluid, equipped with a pressure-temperature indicator for measuring pressure and temperature and also equipped with a flow controller and a flow controller for measuring flow of the fluid entering and leaving the micro-turbine, respectively, a heat exchanger received the hot working fluid from the piping for cooling the fluid using cold matter before returning the cool working fluid to the pump, wherein pressure and temperature of the fluid before entering the pump is measured by using pressure-temperature indicator for pressure and temperature while pressure is regulated by a valve.

The systems described herein, or modifications thereof, can be implemented to provide various methods.

For example, a method of removing heat from a solar panel can include: providing at least one solar panel; circulating a working fluid proximate to the solar panel; and extracting heat from the solar panel via an Organic Rankine Cycle. The method can further include generating electricity based upon the enthalpy of the working fluid. The extracting heat step can include cooling the solar panel so as to increase the efficiency of the solar panels by at least 5% compared to the combined standalone efficiency of the solar panels. The circulating step can include regulating the flow of the working fluid to an operating pressure being lower than the pressure used in a refrigeration cycle.

For example, another method can include: providing at least one solar panel; and affecting the temperature of the solar panel with an organic refrigerant. The affecting the temperature step can include cooling the solar panel so as to increase the efficiency of the solar panels by at least 5% compared to the combined standalone efficiency of the solar panels. The method can further include generating electricity based upon the enthalpy of the organic refrigerant.

For example, another method can include: providing at least one solar panel; moving a working fluid proximate to the solar panel; extracting heat from the solar panel and forming a heated working fluid from the working fluid; and generating electricity from the working fluid. The generating electricity step can include flowing the heated working fluid to an electricity generator and exhausting pressure from the working fluid.

### Solar Panel Heat Energy—Energy Recovery and Storage

As discussed above in the embodiment of FIG. 2, the use of an ORC using a working fluid, such as an organic fluid, to cool solar panel(s) 230 can be used to effectively cool the solar panel 230, increasing the performance efficiency of the solar panel 230 by bringing the temperature of the solar panel 230 closer to an optimum operating temperature. In addition, an electricity generator, such as the turbo-generator 215, can used to extract energy from the boiled working fluid to generate additional electricity.

However, in certain implementations and under certain environmental conditions, the use of an ORC in a single loop solar panel cooling system, such as the solar panel temperature control system 200 of FIG. 2, may have certain limitations. For example, the temperatures of the solar panel 230 may vary significantly based on environmental conditions, including the ambient temperature, amount of cloud cover and/or direct sunlight incident on the solar panel 230, wind speed, time of day, etc. As described above, the extraction of heat from the solar panel 230 into the working fluid via the heat exchanger 210 at least partially boils the working fluid (e.g., the working fluid undergoes a phase change from liquid to gas).

However, when in a gas form, the heat conductance of the working fluid may be lowered, thereby reducing the capacity of the gas liquid fluid to extract excess heat from the solar panel 230. If the working fluid boils sufficiently early along the path the working fluid travels through the heat exchanger 210 (e.g., closer to the inlet of the head exchanger 210), the amount of heat extracted as the working fluid travels through the remainder of the path in the heat exchanger 210 may be significantly reduced. Accordingly, when boiled early along the path within the heat exchanger 210, the amount of heat extracted from the solar panel 230 by the working fluid may be less than the amount of heat extracted if the working fluid is boiled near the end of the path (e.g., closer to the outlet of the heat exchanger 210). It may be possible to control the location at which the working fluid boils along the path by properly controlling the pressure of the working fluid.

Conversely, if the working fluid is not fully boiled prior to leaving the heat exchanger 210, the working fluid may not contain sufficient enthalpy to generate electricity when run through the electricity generator, (e.g., the turbo-generator 215). That is, in some embodiments, the electricity generator may require a gas compressed to a threshold pressure in order to generate electricity. Without sufficiently boiling the working fluid, the energy generation capabilities of the electricity generator may be reduced.

Accordingly, the control of the flow of the working fluid through the heat exchanger 210 can have significant effects on the overall efficiency of the solar panel temperature control system 200. Due to the number of factors which can affect the system efficiency, control of the working fluid (e.g., by increasing the flow rate, controlling the pressure of the fluid, working fluid selection, etc.) may be complex.

### Example Embodiment of Solar Panel Temperature Control and Heat Recovery System

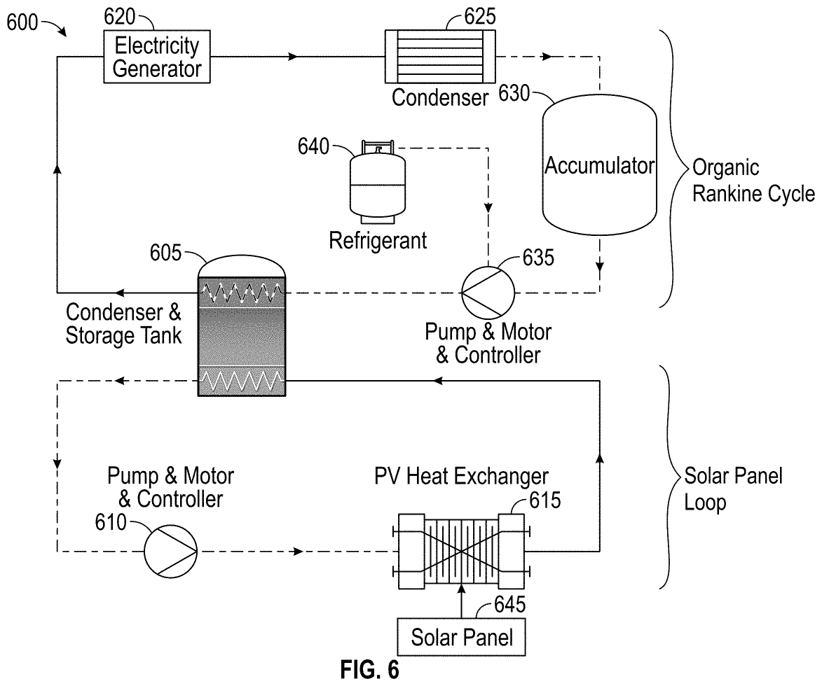

One embodiment of this disclosure which can address at least some of the above limitations is illustrated in FIG. 6. FIG. 6 is a diagram illustrating yet another example of a solar panel temperature control system in accordance with aspects of this disclosure. The system 600 can include a condenser and storage tank 605, a first pump, motor, and controller 610, and a PV heat exchanger 615 configured to exchange heat from a solar panel 645 forming a first loop (also referred to as a solar panel loop). The system 600 can further include an electricity generator 620, a condenser 625, an accumulator 630, a second pump, motor, and controller 635, a refrigerant storage 640, and the condenser and storage tank 605 forming a second loop (also referred to as an ORC loop). As shown in FIG. 6, the first loop may be fluidly separate from the second loop.

The first loop may be configured to cool a solar panel 645 when the solar panel 645 is operating at a temperature that is greater than the solar panel's 645 optimum operating temperature. This may result in increased efficiency in the solar panel's 645 capability to generate electricity similar to the embodiments as described above with reference to FIGS. 2-5. However, in contrast to the above-described embodiments which may use a refrigerant as a working fluid to cool the solar panel 645, in the embodiment of FIG. 6, a first working fluid of the first loop may be a fluid which does not boil when extracting heat from the solar panel 645 via the PV heat exchanger 615. Since the first working fluid in first loop is fluidly isolated from the second working fluid in the second loop (i.e., without fluid communication, or mixing, between the first and second working fluids), and thus does not use the pressure of a gas to generate electricity, the first working fluid does not need to be boiled by the PV heat exchanger 615. Thus, it may be desirable for the first working fluid to extract as much heat as possible from the solar panel 645 via the PV heat exchanger 615 without undergoing a phase change.

Accordingly, the first working fluid in the first loop may comprise a different composition relative to the second working fluid. In some embodiments, the first working fluid may be water or a water-based working fluid. The fluid selected for use as the first working fluid in the first loop may have one or more of the following properties: a relatively high thermal conductivity, a relatively high heat capacity, non-corrosive, safe, non-toxic and nonflammable. Depending on the implementation, the thermal conductivity of the first working fluid may be in the range of 12-20 mW/m·K. However, in many embodiments, the thermal conductivity of the first working fluid may be in the range of 15-20 mW/m·K. In some implementations, the specific heat capacity of the first working fluid may be in the range of 0.9-1.2 J/g·K. However, in many embodiments, the specific heat capacity of the first working fluid may be in the range of 1.0-1.2 J/g·K.

In other embodiments, the first working fluid and the second working fluid may comprise substantially the same compositions. For example, the first and second working fluids may comprise an organic refrigerant. In embodiments where the first working fluid is an organic refrigerant (or another working fluid which is configured to boil when extracting heat from the solar panel 645), the controller 610 may be configured to control the pressure and/or the flow rate of the first working fluid (e.g., using the pump and motor 610) such that the first working fluid boils near the end of the path (e.g., near the outlet of the heat exchanger 615).

Once the first working fluid has been heated by extracting heat from the solar panel 645 via the PV heat exchanger 615, the first working fluid is supplied to the first pump, motor, and controller 610. Using input from one or more sensors, the first controller 610 controls the flow of the first working fluid by providing control signals to the first pump and/or motor 610. The first working fluid is then supplied to the condenser and storage tank 605. As the first working fluid flows through the condenser and storage tank 605, heat is extracted from the first working fluid into the condenser and storage tank 605, thereby cooling the first working fluid before the first working fluid is resupplied to the PV heat exchanger 615.

The condenser and storage tank 605 may comprise a first heat exchanger coupled to the first loop and a second heat exchanger coupled to the second loop. The first heat exchanger may be configured to extract heat from the first working fluid of the first loop and the second heat exchanger may be configured to provide heat to a second working fluid of the second loop (e.g., through transfer of the heat received from the first loop). Thus, the condenser and storage tank 605 may thermally connect the first loop to the second loop, to allow for said heat transfer between the first working fluid and the second working fluid. In other embodiments, the first and second loop may be thermally connected through other configurations suitable to provide thermal communication therebetween, for example, without the use of the condenser and storage tank 605. The condenser and storage tank 605 also accommodates a thermal storage fluid in the storage tank 605 used to store the heat extracted from the first working fluid via the first heat exchanger. The storage tank 605 may store a predetermined volume of the thermal storage fluid such that an expected amount of heat extracted from the PV heat exchanger 615 over a predetermined period of time can be stored by the thermal storage fluid within the tank 605. This can allow for increased flexibility in the timing of when the energy created by the first loop is used to generate electricity by the second loop. The predetermined period of time may be, for example, one day, a set of daylight hours expected to increase the temperature of the solar panel 645 above the optimum operating temperature, etc.

The selection of an appropriate storage tank 605 size may also depend on a number of factors other than the predetermined period of time, at least some of which may be dependent upon the environmental conditions of the particular solar panel 645 temperature control system 600 installation. For example, the size of the storage tank 605 may be selected based on: the expected load of the system 600, the expected excess heat generated by the solar panel(s) 645, the expected length of time the heat energy generated by the solar panel(s) 645 is to be stored, etc.

The second loop may be configured to generate electricity using the thermal energy extracted from the first loop and stored in the condenser and storage tank 605. A second working fluid may be supplied to the second heat exchanger of the condenser and storage tank 605 from which heat is extracted from the storage tank 605 into the second working fluid. The second working fluid may be an organic refrigerant including any of the example organic refrigerants described in connection with the previous solar panel cooling systems (e.g., solar panel temperature control system 200, solar panel temperature control system 300, or solar panel temperature control system 500) disclosed above.

As the second working fluid flows through the second heat exchanger of the condenser and storage tank 605, the second heat exchanger may at least partially boil the second working fluid (e.g., the second working fluid undergoes a phase change from liquid to gas). Under certain conditions, the condenser and storage tank 605 holds sufficient heat to substantially completely boil the second working fluid via the second heat exchanger. Since the condenser and storage tank 605 does not need to be cooled to a certain temperature range (e.g., in contrast to the solar panel 645 which operates more efficiently at certain temperatures), the condenser and storage tank 605 may boil the second working fluid at any point along the path the second working fluid travels within the second heat exchanger. Since the second working fluid may be boiled by the condenser and storage tank 605 and the first working fluid not need to be boiled by the PV heat exchanger 615, the first working fluid may have a boiling point that is greater than a boiling point of the second working fluid.

The boiled second working fluid is supplied to the electricity generator 620. The electricity generator 620 is configured to generate electricity based on the enthalpy of the second working fluid. The electricity generator 620 may be any suitable electricity generator configured to receive the second working fluid and generate electricity based on the enthalpy of the second working fluid. For example, the electricity generator 620 may be configured to generate electricity using the internal energy, pressure and/or volume of the working fluid. Depending on the embodiment, the electricity generator 620 may be any suitable electricity generator, embodied as a turbo-expander, turbo-generator, steam turbine, scroll turbine, etc., and any related components to generate electricity.

The second working fluid can be provided to the condenser 625, or a heat sink, where the second working fluid drops in temperature and re-condenses, for example, before being fed to the accumulator 630. The condenser 625 may be any suitable device configured to receive, cool and condense the second working fluid such that at least a portion of the second working fluid undergoes a partial or complete phase change from gas to liquid. For example, the condenser 625 can be configured to receive the second working fluid from the electricity generator 620, circulate the second working fluid in proximity to a cold source so as to extract heat from the second working fluid into the cold source, such that at least a portion of the second working fluid undergoes a phase change from gas to liquid. The condenser 625 can be configured to supply the second working fluid to the accumulator 630. The accumulator 630 may be configured to remove excess gas from the second working fluid before the second working fluid is supplied to the second pump, motor, and controller 635, such that gas is prevented from reaching the second pump 635. Using input from one or more sensors, the second controller 635 controls the flow of the second working fluid by providing control signals to the second pump and/or motor 635. The second working fluid is then resupplied to the condenser and storage tank 605.

### Example Embodiment of Condenser and Storage Tank

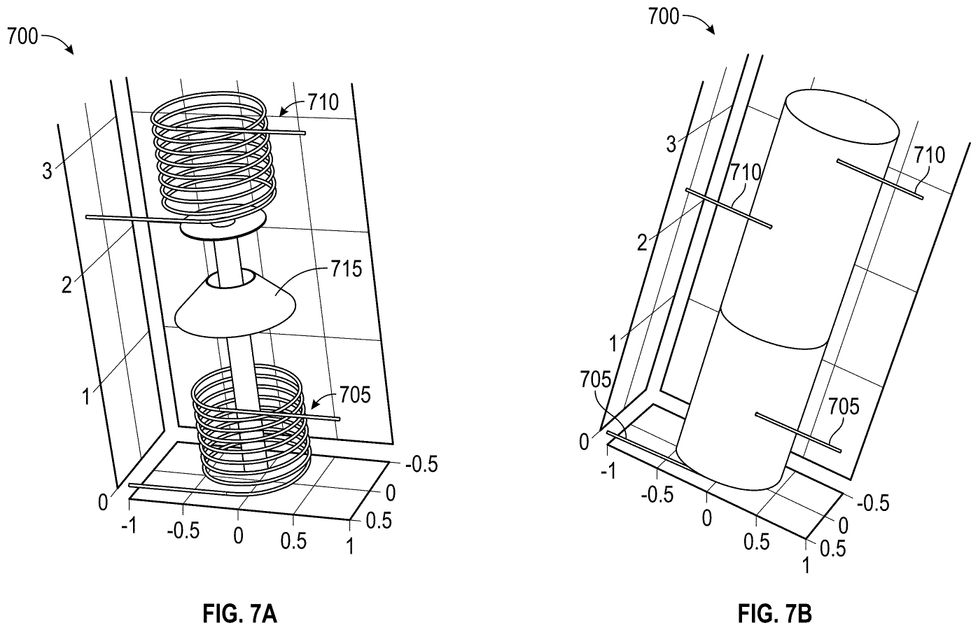

FIGS. 7A and 7B illustrate two views of an example condenser and storage tank which can be used in the system of FIG. 6. Specifically, FIG. 7A illustrates certain internal components of an example condenser and storage tank 700 while FIG. 7B illustrates an external view of the condenser and storage tank 700. Referring to FIGS. 7A and 7B, the condenser and storage tank 700 includes a first heat exchanger 705, a second heat exchanger 710, and a cone separator 715 positioned between the first heat exchanger 705 and the second heat exchanger 710. The first heat exchanger 705 may be connected to the first loop and the second heat exchanger may be connected to the second loop, as illustrated in FIG. 6. In the illustrated embodiment, the second heat exchanger 710 may be located above the first heat exchanger 705, which may result in the thermal storage fluid rising as it is heated by the first heat exchanger 705. The cone separator 715 may aid in maintaining a temperature gradient where higher temperature thermal storage fluid flows to the top of the condenser and storage tank 700 while cooler temperature thermal storage fluid flows to the bottom.

### Example Techniques for Controlling Solar Panel Temperature Control and Heat Recovery System

In addition to the advantages of the two loop solar panel temperature control system 600 of FIG. 6 discussed above, including solving the problem of controlling where an organic refrigerant is boiled when passed through a heat exchanger to cool a solar panel 645, the system 600 may provide additional advantages such as flexibility in selecting when to generate additional electricity by the electricity generator 620. For example, the enthalpy extracted from the solar panels 645 through the PV heat exchanger 615 can be stored in the form of heat in the condenser and storage tank 605 over a period of time without being immediately converted into electricity by the electricity generator 620. Thus, by properly controlling the extraction of heat from the solar panel 645, and selecting the proper timing for extracting the heat energy stored in the condenser and storage tank 605 to generate electricity at the electricity generator 620, the system 600 can: compensate for low electricity generation periods from the solar panel 645, generate additional electricity in response to additional power demands, generate electricity for local consumption rather than relying on the grid, etc.

In order to control each of the first and second loops, the system 600 may further comprise a main controller (not illustrated) to receive output indicative of operating conditions from each of the first and second controller 610 and 635, receive signals from one or more other sensors, and/or provide operations instructions to the first and second controller 610 and 635. As will be appreciated, in other embodiments, the functionality of the main controller may be performed by one of the first and second controller 610 and 635, or a combination thereof, without the inclusion of a separate main controller.

The solar panel temperature control system 600 may include one or more sensors which provide input to one or more of the first and second controller 610 and 635 and the main controller to aid in controlling the cooling and power generating functions of the system. Example sensors which may be incorporated into the system include: temperature sensors (which may sense the temperature of the first working fluid, the second working fluid, the thermal storage fluid, and/or the ambient temperature), pressure sensors (which may measure the pressure of the first and/or second working fluids), current and/or light sensors (which may directly or indirectly measure the amount of light that is incident on the solar panel 645), etc. The first and second controller 610 and 635 and/or the main controller may also receive data from one or more external sources which can be used as an input to adjust the cooling and/or power generation functions of the system. Examples of such external data include: weather forecasts (including temperature, wind, cloud cover, etc.), per unit cost of electricity (which may be predetermined, e.g., based on anticipated usage, or updated in substantial real-time, e.g., based on measured electrical demand of the grid), projected usage requirements (which may be user defined or based on historical electricity usage requirements based on the time of day), time of use rates, etc.

Depending on the electricity requirements of the particular embodiment of the solar panel temperature control system 600, the main controller may use any combination of the listed parameters and may weight the parameters to determine how to control the cooling of the solar panel(s) 645 and the generation of electricity. In one example, the system may receive projected usage requirements which indicate that electricity draw for a certain period of time in the future will exceed the expected power generated by the solar panel(s) 645. The system may then reduce or suspend electricity generation by the electricity generator 620 to maintain the thermal energy in the condenser and storage tank 605 such that the future power demands can be met by both the solar panel(s) 645 and the electricity generator 620 drawing energy from the condenser and storage tank 605.

The main controller may control one, two, and in some embodiments, at least three main functions of the solar panel temperature control system 600 based on the input parameters: toggling cooling of the solar panel(s) 645, toggling storage of heat extracted from the solar panel(s) 645, and toggling electricity generation by the electricity generator 620. In one example, the main controller may determine whether to turn on cooling of the solar panel(s) 645 based on whether the additional electricity generated by the cooled solar panel(s) 645 is greater than the electricity drawn to run the first loop (e.g., to control the pump and motor 610 and any additional sensors in the loop).

In another example, the main controller may determine whether to store heat extracted from the cooling of the solar panel 645 based on: (i) whether the condenser and storage tank 605 has capacity to store additional heat energy. In another example, when the difference in temperature between the heated first working fluid and the thermal storage fluid is less than a threshold value, the condenser and storage tank 605 may not be able to extract enough the heat energy from the first working fluid to overcome the electricity required to extract the heat from the first working fluid. When the storage system is turned off, the condenser and storage tank 605 may cool the first working fluid without extracting heat into the thermal storage fluid (e.g., by using a heat sink other than the thermal storage fluid).

The determination by the main controller of whether to generate electricity with the electricity generator may be based on a number of different parameters, including whether the electricity is more valuable at a later time, whether the condenser and storage tank 605 can effectively store more heat energy, etc. This determination may be continually updated in real-time as the main controller receives updated sensor values and external data.

Although not illustrated, components of the solar panel temperature control system 600 may be designed in a modular fashion and additional components may be added in serial or in parallel. For example, a condenser and storage tank 605 of a given size may only be able to store a predetermined amount of heat energy. Thus, if the cooling of the solar panel(s) 645 generates significantly more heat energy than can be stored in a single condenser and storage tank 605, two or more condenser and storage tanks 605 can be installed, increasing the overall storage capacity of the system 600. Other components may also be added in a modular fashion to address similar issues.

### Example Techniques and Considerations for Energy Conversion

Power generated by solar panels may be characterized by a current-voltage (IV) curve which illustrates the relationship between the electrical current generated by a solar panel and the corresponding generated voltage. PV systems may use a maximum power point tracking (MPPT) technique to maximize the power generated for a solar panel system based on the IV curve of the solar panel. Specifically, the characteristics of the load at the output of the solar panel can be adjusted to a value which produces the highest power efficiency of the solar panel for the current amount of light incident on the panels. The load characteristic which maximizes the power generation efficiency of the solar panel may be referred to as the maximum power point (MPP) which is tracked during MPPT. Accordingly, the main controller and/or the first controller 610 may perform MPPT and adjust the load characteristics at the output of the solar panel 645 so that the solar panel 645 generates electricity at its maximum efficiency.

Electrical power generated by the electricity generator 620 may not have the same IV characteristics as a solar panel 645. Thus, it may be desirable to condition the power generated by the electricity generator 620 so that the electricity can be handled by the MPPT technique employed by the system 600. For example, the electricity generator 620 may be conditioned (e.g., using electricity conditioning circuitry) to simulate the IV curve of a solar panel 645 so that the MPPT technique can be used to adjust the load characteristics at the output of the electricity generator 620. Using this technique, the same MPPT tracking can be used for electricity generated by both the solar panel(s) 645 and the electricity generator 620, simplifying the design of the system 600. In some embodiments, a boost converter or a buck converter may be used to condition the power generated by the electricity generator 620 to have an IV curve similar to that of a solar panel 645.

### Additional Considerations

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

As used herein, the term “plurality” denotes two or more. For example, a plurality of components indicates two or more components. The phrase “based on” does not mean “based only on,” unless expressly specified otherwise. In other words, the phrase “based on” describes both “based only on” and “based at least on.”

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

The previous description of the disclosed implementations is provided to enable any person skilled in the art to make or use the present invention. Various modifications to these implementations will be readily apparent to those skilled in the art, and the generic principles defined herein may be applied to other implementations without departing from the scope of the invention. For example, it will be appreciated that one of ordinary skill in the art will be able to employ a number corresponding alternative and equivalent structural details, such as equivalent ways of fastening, mounting, coupling, or engaging tool components, equivalent mechanisms for producing particular actuation motions, and equivalent mechanisms for delivering electrical energy. Thus, the present invention is not intended to be limited to the implementations shown herein but is to be accorded the widest scope consistent with the principles and novel features disclosed herein.

What is claimed is:

1. A solar panel temperature control system, comprising:
at least one solar panel configured to convert at least a portion of incident light into electrical energy;
a first loop comprising a heat exchanger configured to receive a first working fluid and circulate the working fluid in proximity to the solar panel so as to extract heat from the solar panel into the working fluid; and
a second loop comprising an electricity generator configured to receive a second working fluid and generate electricity based on enthalpy of the second working fluid, the first loop and the second loop being configured to transfer heat from the first working fluid to the second working fluid;
a storage tank configured to extract heat from the first working fluid and provide heat to the second working fluid;
one or more controllers configured to:
store heat extracted from the first working fluid in the storage tank at a first time and provide the stored heat from the storage tank to the second working fluid at a second time.

2. The system of claim 1, wherein the storage tank includes more than one modular storage tank.

3. The system of claim 1, wherein the one or more controllers are configured to control cooling of the solar panel, storing of the heat extracted from the first working fluid in the storage tank, and generating of electricity by the electricity generator, based on one or more parameters.

4. The system of claim 1, wherein the one or more controllers are configured to compensate for low electricity generation periods from the solar panel.

5. The system of claim 1, wherein the one or more controllers are configured to generate additional electricity in response to additional power demands.

6. The system of claim 1, wherein the one or more controllers are configured to generate electricity for local consumption rather than relying on a grid.

7. The system of claim 1, wherein the one or more controllers are configured to receive data from one or more external sources, and use the data as an input to adjust one or more of a cooling function and a power generation function of the system.

8. The system of claim 7, wherein the one or more controllers are configured to receive and use weather forecast data to adjust one or more of a cooling function and a power generation function of the system.

9. The system of claim 7, wherein the one or more controllers are configured to receive and use per unit cost of electricity data to adjust one or more of a cooling function and regulate the optimum time for the power generation function of the system.

10. The system of claim 7, wherein the one or more controllers are configured to receive and use projected usage requirements data to adjust one or more of a cooling function and a power generation function of the system.

11. The system of claim 7, wherein the one or more controllers are configured to receive and use time of use rates data to adjust one or more of a cooling function and a power generation function of the system.

12. The system of claim 1, wherein the one or more controllers are configured to receive projected usage requirements, determine that electricity draw for a certain period of time in the future will exceed the expected power generated by the solar panel, and reduce or suspend electricity generation by the electricity generator to maintain the thermal energy in the storage tank so that future power demands are met by both the solar panel and the electricity generator drawing energy from the storage tank.

13. The system of claim 1, wherein the one or more controllers are configured to determine whether to turn on cooling of the solar panel based on whether the additional electricity generated by the cooled solar panel is greater than the electricity drawn to run the first loop.

14. The system of claim 1, wherein the one or more controllers are configured to determine whether to store heat extracted from the cooling of the solar panel based on whether the storage tank has capacity to store additional heat energy.

15. The system of claim 1, wherein the one or more controllers are configured to determine when the difference in temperature between the heated first working fluid and the thermal storage fluid is less than a threshold value so that the storage tank may not be able to extract enough heat energy from the first working fluid to overcome the electricity required to extract the heat from the first working fluid, and cause the storage tank to cool the first working fluid by using a heat sink without extracting heat into the thermal storage fluid.

16. The system of claim 1, wherein the one or more controllers are configured to determine whether to generate electricity with the electricity generator based on whether the electricity is more valuable at a later time and whether the storage tank can store more heat energy.

17. The system of claim 1, wherein the second loop is configured to cycle the second working fluid via an Organic Rankine Cycle (ORC).

18. The system of claim 1, further comprising electricity conditioning circuitry configured to condition the electricity generated by the electricity generator to simulate an IV curve of the solar panel.

19. The system of claim 1, further comprising one or more of the following sensors that the one or more controllers receiving signals from: temperature sensors that sense one or more of the temperature of the first working fluid, the second working fluid, the thermal storage fluid, and the ambient temperature, pressure sensors that measure the pressure of one or more of the first working fluid and the second working fluids, one or more of current sensor and light sensors that directly or indirectly measure the amount of light that is incident on the solar panel.

20. A method of controlling a solar panel temperature control system, comprising:
converting at least a portion of light incident on at least one solar panel into electrical energy;
circulating a first working fluid in proximity to the solar panel via a heat exchanger so as to extract heat from the solar panel into the working fluid;
transferring heat from the first working fluid into a second working fluid;
extracting heat from the first working fluid into a storage tank at a first time;
providing heat from the storage tank to the second working fluid at a second time after the first time;
generating electricity via an electricity generator based on enthalpy of the second working fluid.
